(19) United States
(12) Patent Application Publication
(10) Pub. No.: US 2015/0179850 A1
(43) Pub. Date: Jun. 25, 2015

(54) RESIN FILM, BACKSHEET FOR SOLAR CELL MODULE, AND SOLAR CELL MODULE

(71) Applicant: Asahi Glass Company, Limited, Tokyo (JP)

(72) Inventor: Hiroshi ARUGA, Tokyo (JP)

(73) Assignee: Asahi Glass Company, Limited, Tokyo (JP)

(21) Appl. No.: 14/641,953

(22) Filed: Mar. 9, 2015

Related U.S. Application Data
(63) Continuation of application No. PCT/JP2013/079315, filed on Oct. 29, 2013.

(30) Foreign Application Priority Data
Oct. 30, 2012 (JP) 2012-239084

(51) Int. Cl. H01L 31/049; C08K 5/5419; C08K 5/521; C08K 3/22; H01L 31/048; C08K 5/5333

(52) U.S. Cl. CPC H01L 31/049; H01L 31/0481; C08K 5/5333; C08K 5/521; C08K 3/22; C08K 5/5419; C08K 2003/2241

(57) ABSTRACT

To provide a resin film having excellent ultraviolet shielding properties, having an excellent outer appearance, further heaving excellent weather resistance, being hardly changeable in optical properties and mechanical properties over a long period of time, and being capable of being formed into a thin film of at most 20 μm, a backsheet provided with the resin film, and a solar cell module provided with the backsheet.

A resin film comprising a resin composition containing a fluororesin (A), particles (B) containing titanium oxide as the main component, a phosphorus compound (C) and a silicone oil (D), wherein the phosphorus compound (C) is at least one member selected from the group consisting of a phosphonite compound (C1), a phosphonate compound (C2) and a phosphate compound (C3) respectively represented by specific formulae and having specific molecular weights, the content of the phosphorus compound (C) is from 0.20 to 2.0 parts by mass per 100 parts by mass of the particles (B), and the content of the silicone oil (D) is from 0.2 to 2.5 parts by mass per 100 parts by mass of the particles (B).

### TECHNICAL FIELD

The present invention relates to a resin film useful for a backsheet for a solar cell module, a backsheet provided with the resin film and a solar cell module provided with the backsheet.

### BACKGROUND ART

A solar cell is a semipermanent and pollution-free energy source which employs sunlight, whereas fossil fuel increases carbon dioxide in the air and greatly deteriorates the global environment. Accordingly, development of various solar cells as an important energy source in future is attempted.

A solar cell is commonly used as a solar cell module having a solar cell element sealed by EVA (ethylene/vinyl acetate copolymer) and its front surface and rear surface sandwiched between a transparent glass substrate and a backsheet (rear side laminate).

A backsheet is provided to protect the EVA and the solar cell element, and it is thereby required to have a strength. Further, since a solar cell module is exposed to the outside for a long period of time, a film constituting the outermost layer of the backsheet (hereinafter sometimes referred to as an outermost film) is required to have sufficient weather resistance. Accordingly, as a backsheet, a PET film excellent in strength is used alone, or in order to suppress hydrolysis or light deterioration of the PET film, a PET film laminated with a resin film excellent in weather resistance as the outermost film, is used in many cases.

A fluororesin film using a fluororesin such as ETFE (ethylene/tetrafluoroethylene copolymer), PVF (polyvinyl fluoride) or PVdF (polyvinylidene fluoride) has been known as a resin film excellent in weather resistance. Among them, an ETFE film and a PVdF film are excellent in moisture resistance in that they are completely free from a decrease in the strength by hydrolysis even when they are left in a test at 85° C. under a relative humidity of 85% (hereinafter sometimes referred to as a 85° C.×relative humidity 85% test) for 1,000 hours. Further, an ETFE film is also excellent in heat resistance in that the temperature at which the elongation is decreased by half by a heat resistance test for 100,000 hours is from about 150 to about 160° C. Accordingly, such a resin film, especially an ETFE film is useful for a backsheet, especially as an outermost film of a backsheet.

The backsheet is required to have a moisture-proof property for suppressing water vapor permeation and thereby protecting a solar cell element from water vapor, but the water vapor permeation cannot sufficiently be suppressed only with a fluororesin film (outermost film). Accordingly, a method of laminating an aluminum foil or a moisture-proof plastic sheet on a fluororesin film to prevent water vapor from entering the solar cell module is employed in many cases. In such a case, with a view to protecting the plastic sheet and an adhesive to be used for lamination from sunlight, the fluororesin film is required to have ultraviolet shielding properties. Specifically, the fluororesin film is required to have an ultraviolet transmittance at a wavelength of at most 360 nm of less than 0.03%.

As a method for imparting ultraviolet shielding properties to a resin film, a method of dispersing an ultraviolet shielding agent to a resin film may be mentioned. As an ultraviolet shielding agent, titanium oxide is used in many cases.

However, since titanium oxide has photoactivity (also referred to as photocatalytic activity), if titanium oxide is dispersed in a fluororesin film, when such a fluororesin film is exposed to the outside, the photoactivity of titanium oxide may impair optical properties and mechanical properties of the fluororesin. Further, even though titanium oxide which is a white pigment is dispersed, the fluororesin may be discolored and no white film may be obtained.

Heretofore, these two problems are overcome by separate means.

To solve the former problem, in order to suppress the photoactivity of titanium oxide, a method of covering the surface of titanium oxide with an inorganic component such as silicon oxide or cerium oxide is commonly employed (for example, Patent Documents 1 to 3).

To solve the latter problem, for example, the above-described Patent Document 3 proposes a method of further treating titanium oxide particles covered with silicon oxide with a hydrophobizing agent such as a silane coupling agent or a silicone oil, and the Document discloses that by hydrophobizing the particle surface, dispersibility into the fluororesin will improve, and discoloration of the fluororesin by agglomeration of the particles can be prevented. Further, the Document discloses that by adding a metallic soap such as a stearate together with a hydrophobizing agent, heat generation by the contact of an oxide in the hydrophobizing agent with a metal member such as a screw or a cylinder of an extruder to be used for film forming, is suppressed, whereby the fluororesin film is less likely to be colored.

Further, it has been proposed to treat the surface of titanium oxide with an organic phosphorus compound when titanium oxide is blended with a resin. For example, Patent Documents 4 and 5 disclose a pigment having a pigment base material such as titanium dioxide treated with a specific organic phosphate compound. Such a pigment is considered to impart improved physical properties and chemical properties (lacing resistance, improved dispersion and reduced chemical reactivity) when incorporated into a polymer matrix. Patent Document 6 discloses a flame retardant polycarbonate resin composition having titanium oxide surface-treated with a phosphorylated polyene blended in a polycarbonate resin. If titanium oxide not surface-treated with a phosphorylated polyene is used, such a resin composition is considered to be unfavorable since it is inferior in light reflectivity and mechanical properties.

Use of cerium oxide, although not titanium oxide, and an antioxidant in combination has also been proposed. For example, Patent Document 7 discloses to incorporate a phosphite antioxidant together with a cerium oxide fine powder into a fluororesin film. Patent Document 8 discloses to incorporate, in reuse of a fluororesin film having a layer of an agricultural anti dew drops coating comprising an inorganic component such as silica, a phosphite antioxidant into such a film. In Patent Documents 7 and 8, as the antioxidant, a phosphite antioxidant is used.

Patent Document 9 discloses an anti-fouling sheet comprising a substrate layer containing at least one thermoplastic resin composition layer and formed on at least one surface of the substrate layer, a surface layer containing a photocatalyst, wherein an antioxidant is incorporated into the thermoplastic resin composition layer closest to the surface layer, discloses use as the antioxidant a phenol, phosphite, sulfur or vitamin E antioxidant, and discloses that the antioxidant scavenge active oxygen which influences the thermoplastic resin composition layer among active oxygens generated by the photocatalytic activity of titanium oxide and has an effect to prevent the thermoplastic resin composition from being decomposed and deteriorated by the photocatalyst.

### PRIOR ART DOCUMENTS

### Patent Documents

Patent Document 1: JP-A-8-259731
Patent Document 2: WO2008/078704
Patent Document 3: WO2010/067803
Patent Document 4: JP-A-2004-522815
Patent Document 5: JP-A-2007-224307
Patent Document 6: JP-A-2003-105188
Patent Document 7: JP-A-10-147681
Patent Document 8: JP-A-11-323008
Patent Document 9: JP-A-2003-19775

### DISCLOSURE OF INVENTION

### Technical Problem

In recent years, a solar cell module has been required to have further improved durability. Further, the solar cell module is less likely to be installed in roof-integrated system, and is instead installed independently in an installation site such as a roof, in many cases. Especially, it is often installed on the slant at an optimum angle so that the transparent glass substrate faces the sun depending on the latitude at the installation site. In such an installation method, a large quantity of reflected light of sunlight is applied to the backsheet at the rear side of the solar cell module. Therefore, the outermost film of the backsheet is also required to have more excellent weather resistance (such as light resistance and heat resistance).

Specifically, in a weather resistance test by a carbon arc sunshine weather meter (SWM) (the exposure by SWM for from 250 to 500 hours corresponds to the outdoor exposure for one year), the film was heretofore required to have an weather resistance to such an extent that at least 50% of initial breaking strength is retained after the exposure for 5,000 hours (corresponding to the outdoor exposure for 10 to 20 years). However, in recent years, it has been required to sufficiently retain optical properties such as solar reflectance or ultraviolet shielding properties, or mechanical properties such as breaking strength (for example, at least 80% of initial breaking strength is retained), even after the exposure for 10,000 hours by SWM. Further, the evaluation time of the 85° C.×relative humidity 85% test for observing the extent of hydrolysis has been conventionally 1,000 hours, but is 3,000 hours in recent years.

Further, the thickness of a fluororesin film to be used for the outermost film has been conventionally about 25 μm, but in recent years, it has been required to make it thinner, for example, 20 μm or 15 μm, in order to reduce costs. However, if a fluororesin film having titanium oxide dispersed so as to impart ultraviolet shielding properties is merely made to be thinner, the ultraviolet shielding properties are deteriorated. Further, due to light irradiation, titanium oxide particles will move to the vicinity of a film surface layer with time, whereby the solar reflectance of the film tends to change or the film tends to be whitened.

Accordingly, the outermost film of the backsheet is required to be a fluororesin film showing excellent ultraviolet shielding properties even when the film is made to be a thin film having a thickness of at most 20 μm, having an excellent outer appearance, further having excellent weather resistance and being less likely to change in optical properties or mechanical properties for a long period of time.

In a conventional technique, a fluororesin film fully satisfying the above requirements has not been obtained.

For example, the film disclosed in Patent Document 1 is for agricultural greenhouses, membrane structures, etc., and is a film having a thickness of approximately from 100 to 250 μm so as to have translucency or transparency as to transmit at least 40% of visible rays and to have a sufficient strength, and the concentration of titanium oxide contained in the film is less than 5 mass %. On the other hand, the outermost film of the backsheet is required to have the weather resistance and ultraviolet shielding properties equal to or higher than those of a film for agricultural greenhouses, etc., and further, as mentioned above, it is required to be so thin as at most 20 μm. Accordingly, in a case where the film disclosed in Patent Document 1 is used as the outermost film of the backsheet, it is necessary to disperse titanium oxide in a larger amount per unit volume, so as to impart ultraviolet shielding properties (an ultraviolet transmittance at a wavelength of at most 360 nm being less than 0.03%) which is required for the outermost film of the backsheet. However, if titanium oxide in a large amount necessary for imparting required ultraviolet shielding properties is covered with silicon oxide in a large amount for suppressing its catalytic activity and contained in a fluororesin film, bubble streaks are likely to form by bubbling of water contained in silicon oxide, whereby the film is defective in some cases. If such a covering amount is reduced to solve the problem, a covering effect tends to be insufficient, whereby a resin tends to be deteriorated, or the mechanical properties tend to be decreased along with the deterioration.

Patent Documents 2 and 3 propose use of composite particles having photoactivity reduced by covering titanium oxide surface with cerium oxide or silicon oxide, however, if titanium oxide is covered with a large amount of silicon oxide or cerium oxide sufficient to suppress the photoactivity and such titanium oxide is incorporated in a fluororesin film, bubble streaks may form due to bubbling of water contained in silicon oxide or cerium oxide, whereby the film tends to be defective, in the same manner as described for Patent Document 1. If such a covering amount is reduced to solve the problem, a covering effect tends to be insufficient, whereby a resin tends to be deteriorated, or the mechanical properties tend to be decreased along with the deterioration.

Patent Documents 4 and 5 disclose that by treating titanium dioxide with a specific organic phosphate compound, bubble streaks are reduced (the lacing resistance is improved) when a polyethylene film containing such titanium dioxide is formed, dispersibility of titanium oxide is improved, and coloring by the compound is suppressed.

However, according to studies by the present inventor, when titanium oxide surface-treated with an organic phosphate compound as disclosed in Patent Document 4 or 5 is incorporated in a fluororesin particularly ETFE to form a film, a strong unpleasant odor is emitted at the time of film forming. Further, a large amount of a decomposed product of the organic phosphate compound is formed and remarkably deteriorates the outer appearance of the film. This is considered to be due to a high forming temperature for a fluororesin film as compared with polyethylene or the like, and thus decomposition of the organic phosphate compound at the forming temperature.

Even when titanium oxide surface-treated with a phosphorylated polyene as disclosed in Patent Document 6 is incorporated in a fluororesin particularly ETFE to form a film, a large amount of a decomposed product of a phosphorylated polyene may be formed and remarkably deteriorate the film outer appearance, in the same manner as the organic phosphate compound.

The present inventor has studied to incorporate an antioxidant as disclosed in Patent Documents 7 to 9 together with titanium oxide. However, according to the studies, when such an antioxidant is incorporated, although an improvement to a certain extent is obtained, the weather resistance should further be improved. For example, in a case where a phosphite antioxidant which is considered to be favorable in Patent Documents 7 to 9 is added to an ETFE film together with titanium oxide, although yellowing of the film was suppressed, the suppression effect does not last over a long period, as is required for a solar cell module. This is considered to be because such an antioxidant may suppress decomposition and discoloration by oxidation to a certain extent by scavenging active oxygen, but it may not suppress the photoactivity of titanium oxide.

Further, if a phosphite antioxidant is used, an unpleasant odor due to a decomposed product may be emitted at the time of forming.

The present invention has been made under these circumstances, and it is an object of the present invention to provide a resin film having excellent ultraviolet shielding properties, having an excellent outer appearance, further having excellent weather resistance, being hardly changeable in optical properties and mechanical properties for a long period of time, and being capable of being formed into a thin film of at most 20 μm; a backsheet provided with the resin film; and a solar cell module provided with the backsheet.

### Solution to Problem

The present inventor has conducted extensive studies and as a result, found that a specific phosphorus compound has an effect to effectively suppress the photoactivity of titanium oxide, and by incorporating a specific amount of the phosphorus compound in a fluororesin film, a decrease in the optical properties and mechanical properties can be suppressed over a long period of time, and an unpleasant odor at the time of film forming is less likely to be emitted, even though titanium oxide is not covered with silicon oxide or cerium oxide. Further, he has found that by using a specific amount of a silicone oil in combination with the phosphorus compound, coloring and fisheyes at the time of film forming can be suppressed, and a fluororesin film having an excellent outer appearance can be obtained.

The present invention has been made based on the above findings, and provides a resin film, a backsheet for a solar cell module and a solar cell module according to the following [1] to [15].

[1] A resin film comprising a resin composition containing a fluororesin (A), particles (B) containing titanium oxide as the main component, a phosphorus compound (C) and a silicone oil (D), wherein

the phosphorus compound (C) is at least one member selected from the group consisting of a phosphonite compound (C1) represented by the following formula (1) having a molecular weight of from 600 to 1,500, a phosphonate compound (C2) represented by the following formula (2) having a molecular weight of from 400 to 1,500, and a phosphate compound (C3) represented by the following formula (3) having a molecular weight of from 400 to 1,500,

the content of the phosphorus compound (C) is from 0.20 to 2.0 parts by mass per 100 parts by mass of the particles (B), and

the content of the silicone oil (D) is from 0.2 to 2.5 parts by mass per 100 parts by mass of the particles (B):

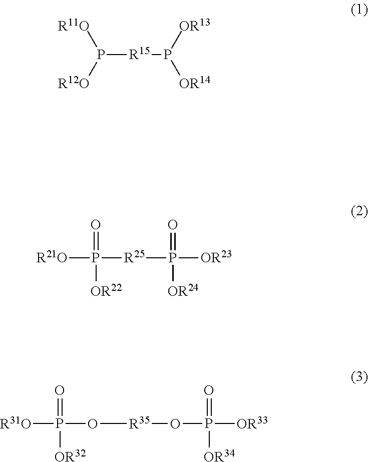

[in the formula (1), each of R¹¹ to R¹⁴ which are independent of one another, is an alkyl group or an aryl group which may have an alkyl group, and R¹⁵ is a bivalent hydrocarbon group; in the formula (2), each of R²¹ to R²⁴ which are independent of one another, is an alkyl group or an aryl group which may have an alkyl group, and R²⁵ is a bivalent hydrocarbon group; and in the formula (3), each of R³¹ to R³⁴ which are independent of one another, is an alkyl group or an aryl group which may have an alkyl group, and R³⁵ is a bivalent hydrocarbon group.]
[2] The resin film according to [1], wherein each of R¹⁵, R²⁵ and R³⁵ is an alkylene group or an arylene group.
[3] The resin film according to [1] or [2], wherein the phosphorus compound (C) has a phosphorus atom content of from 4 to 12 mass %.
[4] The resin film according to any one of [1] to [3], wherein the phosphonite compound (C1) has a molecular weight of from 1,000 to 1,500, the phosphonate compound (C2) has a molecular weight of from 900 to 1,500, and the phosphate compound (C3) has a molecular weight of from 600 to 1,500.
[5] The resin film according to any one of [1] to [4], wherein the fluororesin (A) is an ethylene/tetrafluoroethylene copolymer.
[6] The resin film according to [5], wherein the phosphorus compound (C) has a melting point of at most 240° C.
[7] The resin film according to any one of [1] to [6], wherein the particles (B) are particles having a titanium oxide content of at least 95 mass % and an average particle size of from 0.15 to 0.40 μm.
[8] The resin film according to any one of [1] to [7], wherein the content of the particles (B) is from 2 to 15 parts by mass per 100 parts by mass of a resin component in the resin composition.
[9] The resin film according to any one of [1] to [8], wherein the silicone oil (D) is dimethyl silicone oil or phenyl methyl silicone oil.
[10] The resin film according to any one of [1] to [9], which has a thickness of from 12 to 300 μm.
[11] The resin film according to any one of [1] to [10], which is a film obtained by extruding the resin composition into a film.
[12] The resin film according to any one of [1] to [11], which is used for a backsheet for a solar cell module.
[13] A backsheet for a solar cell module, which has the resin film as defined in any one of [1] to [12].
[14] The backsheet for a solar cell module according to [13], which has the resin film as the outermost layer.
[15] A solar cell module provided with the backsheet as defined in [13] or [14].

### Advantageous Effects of Invention

According to the present invention, it is possible to provide a resin film having excellent ultraviolet shielding properties, having an excellent outer appearance, further having excellent weather resistance, being hardly changeable in optical properties and mechanical properties over a long period of time, and being capable of being formed into a thin film of at most 20 μm; a backsheet provided with the resin film; and a solar cell module provided with the backsheet.

### BRIEF DESCRIPTION OF DRAWINGS

FIG. 1 is a cross-sectional view illustrating one embodiment of the backsheet for a solar cell module.

FIG. 2 is a schematic cross-sectional view illustrating another embodiment of the backsheet for a solar cell module.

### DESCRIPTION OF EMBODIMENTS

### Resin Film

The resin film according to a first embodiment of the present invention comprises a resin composition containing a fluororesin (A), particles (B) containing titanium oxide as the main component, a phosphorus compound (C) and a silicone oil (D).

In the resin composition, the phosphorus compound (C) is at least one member selected from the group consisting of a phosphonite compound (C1) represented by the formula (1) having a molecular weight of from 600 to 1,500, a phosphonate compound (C2) represented by the formula (2) having a molecular weight of from 400 to 1,500 and a phosphate compound (C3) represented by the formula (3) having a molecular weight of from 400 to 1,500, the content of the phosphorus compound (C) is from 0.20 to 2.0 parts by mass per 100 parts by mass of the particles (B), and the content of the silicone oil (D) is from 0.2 to 2.5 parts by mass per 100 parts by mass of the particles (B).

### [Fluororesin (A)]

The resin composition in the present invention contains at least the fluororesin (A).

The fluororesin (A) may, for example, be an ethylene/tetrafluoroethylene copolymer, a vinyl fluoride polymer, a vinylidene fluoride polymer, a vinylidene fluoride/hexafluoropropylene copolymer, a tetrafluoroethylene/hexafluoropropylene/vinylidene fluoride copolymer, a tetrafluoroethylene/propylene copolymer, a tetrafluoroethylene/vinylidene fluoride/propylene copolymer, a hexafluoropropylene/tetrafluoroethylene copolymer or a perfluoro(alkyl vinyl ether)/tetrafluoroethylene copolymer. The fluororesin (A) contained in the resin composition may be one type or two or more types.

Among them, the fluororesin (A) is preferably an ethylene/tetrafluoroethylene copolymer (hereinafter sometimes referred to as ETFE) in view of excellent weather resistance and heat resistance.

### (ETFE)

ETFE is a copolymer having structural units based on tetrafluoroethylene (hereinafter sometimes referred to as TFE units) and structural units based on ethylene (hereinafter sometimes referred to as ethylene units).

In ETFE, the molar ratio (TFE units/ethylene units) of TFE units to ethylene units is preferably from 20/80 to 80/20, more preferably from 30/70 to 70/30, furthermore preferably from 40/60 to 60/40.

ETFE may contain, in addition to the TFE units and the ethylene units, structural units based on another monomer. However, the proportion of the repeating units based on such another monomer is preferably at most 10 mol %, more preferably at most 6 mol %, furthermore preferably at most 3 mol %, based on the total (100 mol %) of the entire structural units of ETFE.

Such another monomer may, for example, be a fluoroethylene (excluding TFE) such as CF₂═CFCl or CF₂═CH₂; a C₃₋₅ perfluoroolefin such as hexafluoropropylene or octafluorobutene-1; a polyfluoroalkylethylene represented by X¹ (CF₂)ₙCY¹═CH₂ (wherein X¹ and Y¹ are each independently a hydrogen atom or a fluorine atom, and n is an integer of from 2 to 8); a perfluorovinyl ether such as R^{f}(OCFX²CF₂)ₘOCF═CF₂ (wherein R^{f} is a C₁₋₆ perfluoroalkyl group, X² is a fluorine atom or a trifluoromethyl group, and m is an integer of from 0 to 5); a perfluorovinyl ether having a group capable of easily converted to a carboxylic acid group or a sulfonic acid group, such as CH₃OC(═O)CF₂CF₂CF₂OCF═CF₂ or FSO₂CF₂CF₂OCF(CF₃)CF₂OCF═CF₂; a perfluorovinyl ether having at least two unsaturated bonds, such as CF₂═CFOCF₂CF═CF₂ or CF₂═CFO(CF₂)₂CF═CF₂; a fluoromonomer having an alicyclic structure such as perfluoro(2,2-dimethyl-1,3-dioxol), 2,2,4-trifluoro-5-trifluoromethoxy-1,3-dioxol or perfluoro(2-methylene-4-methyl-1,3-dioxolane); or an olefin having at least 3 carbon atoms, such as propylene, butylene or isobutylene.

Among them, in the polyfluoroalkylethylene represented by X¹(CF₂)ₙCY¹═CH₂, n is preferably an integer of from 2 to 6, more preferably an integer of from 2 to 4. Its specific examples include CF₃CF₂CH═CH₂, CF₃CF₂CF₂CF₂CH═CH₂, CF₃CF₂CF₂CF₂CF═CH₂, CF₂HCF₂CF₂CF═CH₂ and CF₂HCF₂CF₂CF═CH₂.

Specific examples of the perfluorovinyl ether such as R^{f}(OCFX²CF₂)ₘOCF═CF₂, include perfluoro(methyl vinyl ether), perfluoro(ethyl vinyl ether), perfluoro(propyl vinyl ether), CF₂═CFOCF₂CF(CF₃)O(CF₂)₂CF₃, CF₂═CFO(CF₂)₃O(CF₂)₂CF₃, CF₂═CFO(CF₂CF(CF₃)O)₂(CF₂)₂CF₃ and CF₂═CFOCF₂CF(CF₃)O(CF₂)₂CF₃.

Another monomer in ETFE is preferably the above polyfluoroalkylethylene, hexafluoropropylene or perfluoro(propyl vinyl ether), more preferably CF₃CF₂CH═CH₂, CF₃(CF₂)₃CH═CH₂, hexafluoropropylene or perfluoro(propyl vinyl ether). Such other monomers may be used alone or in combination of two or more.

The number average molecular weight of ETFE is not particularly limited, and is preferably from 100,000 to 500,000, more preferably from 200,000 to 400,000. When the number average molecular weight of ETFE is at least the lower limit of the above range, the strength will hardly be decreased in the heat resistance test. Further, when the number average molecular weight of ETFE is at most the upper limit of the above range, formation of a thin film having a thickness of at most 20 μm, for example at a level of 10 μm, will be easy.

The number average molecular weight of ETFE is a value obtained in accordance with the following procedure. Using a rheometer (DAR100) manufactured by Reologica, a molten dynamic shear modulus is measured to obtain the relation between the frequency (ω) and the dynamic modulus. Then, on the basis of a reference (W. H. Tuminello, Macromolecules, 1993, 26, 499-50), a molecular weight is obtained from the frequency by conducting fitting so that the relation between the frequency and the molecular weight M would be 1/ω=CM^{3.4} (C: constant), followed by conversion to a differential molecular weight distribution curve, whereby a number average molecular weight is calculated. Further, GNO (plateau modulus) corresponding to an elastic modulus of the entanglement molecular weight is 3.5×10⁶ dyne/cm².

In a case where the resin composition contains ETFE, it may further contain a fluororesin other than ETFE. Since ETFE is less compatible with such other fluororesins and further has a high mechanical strength, the proportion of ETFE in the resin composition is preferably at least 90 mass %, more preferably at least 98 mass %, particularly preferably 100 mass %, based on the entire fluororesin (100 mass %) contained in the resin composition. That is, it is particularly preferred that the fluororesin (A) in the resin composition is only ETFE.

The resin composition may contain a resin other than the fluororesin (A) as the resin component.

Such a resin may, for example, be an acryl resin, a polycarbonate resin, a polyethylene resin, a polypropylene resin, a polyethylene terephthalate, a polybutylene terephthalate or nylon.

However, the proportion of the fluororesin (A) based on the resin component (in a case where a resin other than the fluororesin (A) is contained, including the resin) in the resin composition is at least 50 mass %. When the proportion of the fluororesin (A) based on the resin component is at least 50 mass %, the weather resistance, the chemical resistance and the like will be excellent.

The proportion of the fluororesin (A) based on the resin component in the resin composition is preferably at least 90 mass %, more preferably at least 98 mass %, particularly preferably 100 mass %. That is, it is particularly preferred that the entire resin component in the resin composition is the fluororesin (A). Especially, it is most preferred that the entire resin component in the resin composition is ETFE.

### [Particles (B)]

The particles (B) are particles containing titanium oxide as the main component.

“Main component” means that the content of titanium oxide in the particles (B) is at least 95 mass %. The content of titanium oxide in the particles (B) is preferably at least 97 mass %.

The particles (B) may be titanium oxide particles (the titanium oxide content being 100 mass %), or may be composite particles having a cover layer on the surface of titanium oxide particles. The cover layer may be a single layer or a multilayer.

The cover layer may, for example, be a layer containing an inorganic component such as silicon oxide, cerium oxide, aluminum oxide, phosphorus oxide, sodium oxide, zirconium oxide or cerium oxide. However, for the purpose of obtaining a resin film excellent in the weather resistance and the outer appearance, the content of inorganic components having water of crystallization which may lead to bubbling (such as silicon oxide, cerium oxide and aluminum oxide) is preferably within 3 mass % in the particles (B).

Further, the inorganic components in the particles (B) may be quantified using a press sheet of particles (B) by means of a scanning type fluorescent X-ray spectrometer (such as ZSX Primus II manufactured by Rigaku Corporation).

As the particles (B), products prepared by a known production method may be used, or commercially available products may be used.

As the commercially available product which may be used as the particles (B), R101, R102, R103 and R104 manufactured by Du Pont; RCL-69 and TiONA188 manufactured by Millennium Inorganic Chemicals; 2230 and 2233 manufactured by Kronox; CR50 and CR63 manufactured by Ishihara Sangyo Kaisha, Ltd.; and CR470 manufactured by Tronox may, for example, be mentioned. The content of titanium oxide in each of these products is at least 96 mass % as analytical values by the manufacturers.

Some of commercially available titanium oxide products are preliminarily surface-treated with an organic substance such as a silicone oil, however, the amount of the organic substance used for the surface treatment is very small. Thus, in a case where a commercially available titanium oxide product is used, even if a silicone oil is contained as the organic substance, the amount of the silicone oil is not counted as the content of the silicone oil (D) and is included in the content of the particles (B).

The average particle size of the particles (B) is preferably from 0.15 to 0.40 μm, more preferably from 0.17 to 0.30 μm.

If the average particle size of the particles (B) is at least the lower limit of the above range, the photoactivity is less likely to be exhibited since the specific surface area of the titanium oxide particles is small, and the effect of the present invention tends to sufficiently be obtained. When the average particle size of the particles (B) is at most the upper limit of the above range, excellent ultraviolet shielding properties (ultraviolet transmittance at a wavelength of at most 360 nm: at most 0.03%) being expected to a backsheet of a solar cell module tend to be obtained.

In this specification, the average particle size is a value obtained in such a manner that particle sizes of 20 particles randomly extracted by an electron microscope are measured and averaged.

The content of the particles (B) in the resin composition is preferably from 2 to 15 parts by mass, more preferably from 5 to 12 parts by mass, further preferably from 6 to 11 parts by mass, per 100 parts by mass of the resin component.

When the content of the particles (B) is at least the lower limit of the above range, most of the ultraviolet rays are absorbed in the particles (B) in the vicinity of the surface layer of the resin film and are blocked out, and thus they hardly enter the interior of the resin film, and accordingly it is likely to prevent the ultraviolet rays from reaching the whole resin film to develop the photoactivity.

When the content of the particles (B) is at most the upper limit of the above range, the particles (B) are likely to be dispersed in the resin component, and a resin film formed from such a resin composition tends to be excellent in the outer appearance. Further, the obtained resin film is also excellent in the mechanical strength.

The development of the photoactivity is observed as a whitening phenomenon in which the surface of the film will be whiter by exposure to the outside or in an accelerated weather resistance test. That is, if the photoactivity is exhibited by the exposure to the outside or the accelerated weather resistance test, the binding power of the fluororesin (A) will be decreased, whereby the particles (B) uniformly dispersed in the film will move to the surface layer (a surface exposed to light and water), the concentration of titanium oxide on the surface layer is increased, and accordingly a decrease in the ultraviolet transmittance and an increase in the solar reflectance are induced. This phenomenon is observed as a whitening phenomenon. For the backsheet of a solar cell module, especially for the outermost film, a low ultraviolet transmittance and a high solar reflectance are preferred. Of a film which undergoes such whitening phenomenon, mechanical strength especially breaking strength is deteriorated, and therefore such a film hardly has a high reliability for a long period of time. Further, in view of e.g. a good outer appearance, the values of the ultraviolet transmittance and the solar reflectance are preferably not changed during use.

### [Phosphorus Compound (C)]

The phosphorus compound (C) contained in the resin composition is at least one member selected from the group consisting of the following phosphonite compound (C1), the following phosphonate compound (C2) and the following phosphate compound (C3).

The phosphorus compound (C) has a function to suppress the photoactivity of titanium oxide contained in the particles (B).

### (Phosphonite Compound (C1))

The phosphonite compound (C1) is a compound represented by the following formula (1) having a molecular weight of from 600 to 1,500:

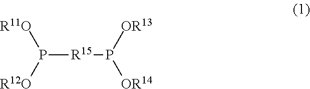

wherein each of R¹¹ to R¹⁴ which are independent of one another, is an alkyl group or an aryl group which may have an alkyl group, and R¹⁵ is a bivalent hydrocarbon group.

In the formula (1), the alkyl group in each of R¹¹ to R¹⁴ may be linear, branched or cyclic. The number of carbon atoms in the alkyl group is not limited so long as the molecular weight of the phosphonite compound (C1) is within a range of from 600 to 1,500, and is preferably from 1 to 18.

The aryl group in each of R¹¹ to R¹⁴ may, for example, be a monocyclic aryl group such as a phenyl group, a condensed polycyclic aryl group such as a naphthyl group, or a linked polycyclic aryl group. The linked polycyclic aryl group is a monovalent group having monocyclic or condensed polycyclic aromatic rings linked directly or via an alkylene group or the like. The aryl group may have an alkyl group, and such an alkyl group may be linear, branched or cyclic, and preferably has from 1 to 8 carbon atoms.

R¹¹ to R¹⁴ may be the same or different from one another.

As each of R¹¹ to R¹⁴, among them, preferred is an aryl group which may have an alkyl group, and more preferred is a phenyl group which may have an alkyl group.

The bivalent hydrocarbon group as R¹⁵ may, for example, be an alkylene group or an arylene group.

The alkylene group may be linear, branched or cyclic. The number of carbon atoms in the alkylene group is not limited so long as the molecular weight of the phosphonite compound (C1) is within a range of from 600 to 1,500, and is preferably from 1 to 30. Particularly, the number of carbon atoms in the cyclic alkylene group (cycloalkylene group) is more preferably from 5 to 12.

The arylene group may, for example, be a monocyclic arylene group such as a phenylene group, a condensed polycyclic arylene group such as a naphthylene group, or a linked polycyclic arylene group. “The linked polycyclic arylene group” is a bivalent group having monocyclic or condensed polycyclic aromatic rings linked directly or via an alkylene group or the like. The alkylene group linking the aromatic rings is preferably an alkylene group having at most 6 carbon atoms. Further, the arylene group may have an alkyl group.

The linked polycyclic arylene group may, for example, be a biarylene group such as a biphenylene group represented by the following formula (15-1) or a linked polycyclic arylene group represented by the following formula (15-2).

R¹⁵ is preferably an arylene group, more preferably a phenylene group, a biphenylene group or a linked phenylene group having phenylene groups linked via an alkylene group, particularly preferably a biphenylene group.

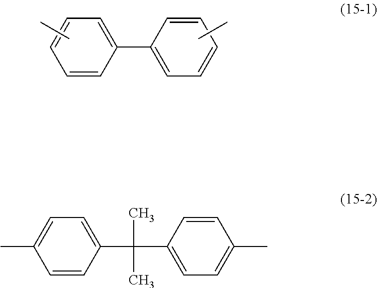

The molecular weight of the phosphonite compound (C1) is from 600 to 1,500, and is preferably from 1,000 to 1,500. The molecular weight relates to the decomposition temperature of the phosphonite compound (C1). A compound having a molecular weight of at least 600 has a sufficiently high decomposition temperature, and it hardly generates a decomposition gas in the compounding step and in the film-formation step and provides excellent work environment. Further, a compound having a molecular weight within the above range has an excellent effect to suppress the photoactivity of titanium oxide. This is considered to be because the phosphonite compound (C1) is uniformly oriented in titanium oxide. Further, foreign matters due to agglomeration of the phosphonite compound (C1) itself hardly form.

The phosphorus atom content (the proportion of the mass of phosphorus atoms based on the total mass (100 mass %) of all the atoms) in the phosphonite compound (C1) is preferably at a level of from 4 to 12%.

The melting point of the phosphonite compound (C1) is preferably at most the melting point of the fluororesin (A). For example, in a case where the fluororesin (A) is ETFE having a melting point of 240° C., the phosphonite compound (C1) is preferably a compound having a melting point of at most 240° C.

Specific examples of the phosphonite compound (C1) include a compound represented by the following formula (I-1) (tetrakis(2,4-di-t-butyl-5-methylphenyl)[1,1-biphenyl]-4,4′-diylbisphosphonite, molecular weight: 1,092, melting point: 234 to 240° C.), and a compound represented by the following formula (1-2) (tetrakis(2,4-di-tert-butylphenyl){1,1-biphenyl}-4,4′-diylbisphosphonite, molecular weight: 1,035, melting point: 93 to 99° C.).

As the phosphonite compound (C1), commercially available products may be used, and products prepared by a known production process may be used. For example, the compound represented by the formula (1-1) may be available as “GSY-P101” manufactured by Osaki Industry Co., Ltd. The compound represented by the formula (1-2) may be available as “IRGAFOS P-EPQ” manufactured by Ciba Specialty Chemicals.

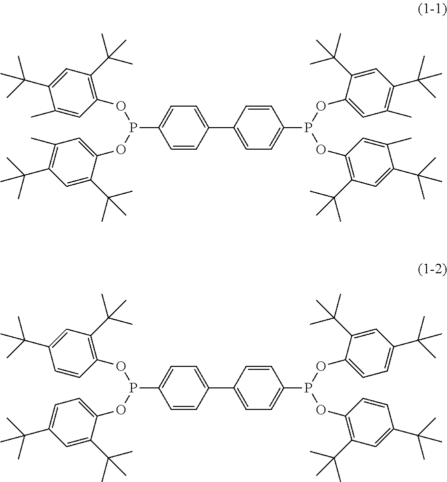

### (Phosphonate Compound (C2))

The phosphonate compound (C2) is a compound represented by the following formula (C2) having a molecular weight of from 400 to 1,500:

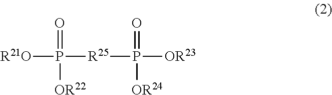

wherein each of R²¹ to R²⁴ which are independent of one another, is an alkyl group or an aryl group which may have an alkyl group, and R²⁵ is a bivalent hydrocarbon group.

In the formula (2), the alkyl group or the aryl group which may have an alkyl group in each of R²¹ to R²⁴ may be the same as the alkyl group or the aryl group which may have an alkyl group in each of R¹¹ to R¹⁴.

R²¹ to R²⁴ may be the same or different from one another.

As each of R²¹ to R²⁴, among the above, preferred is an aryl group which may have an alkyl group, and more preferred is a phenyl group which may have an alkyl group.

The bivalent hydrocarbon group in R²⁵ may be the same group as the bivalent hydrocarbon group as R¹⁵.

R²⁵ is preferably an arylene group, more preferably a phenylene group, a biphenylene group or a linked phenylene group having phenylene groups linked via an alkylene group, and particularly preferably a biphenylene group.

The molecular weight of the phosphonate compound (C2) is from 400 to 1,500, preferably from 900 to 1,500. The molecular weight relates to the decomposition temperature of the phosphonate compound (C2). A compound having a molecular weight of at least 400 has a sufficiently high decomposition temperature, and hardly generates a decomposition gas in the compounding step and the film-formation step, and provides excellent work environment. Further, a compound having a molecular weight within the above range has an excellent effect to suppress the photoactivity of titanium oxide. This is considered to be because the phosphonate compound (C2) is uniformly oriented in titanium oxide. Further, foreign matters due to agglomeration of the phosphonate compound (C2) itself hardly form.

The phosphorus atom content in the phosphonate compound (C2) is preferably at a level of from 4 to 12%.

The melting point of the phosphonate compound (C2) is preferably at most the melting point of the fluororesin (A). For example, in a case where the fluororesin (A) is ETFE having a melting point of 240° C., the phosphonate compound (C2) is preferably one having a melting point of at most 240° C.

Specific examples of the phosphonate compound (C2) include a compound represented by the following formula (2-1) (tetraethylbiphenyl-4,4′-diyldiphosphonate, molecular weight: 426) and a compound represented by the following formula (2-2) (tetradodecylbiphenyl-4,4′-diyldiphosphonate, molecular weight: 986).

As the phosphonate compound (C2), commercially available products may be used, and products prepared by a known production process may be used. For example, the compound represented by the formula (2-2) may be available from JOHOKU CHEMICAL CO., LTD.

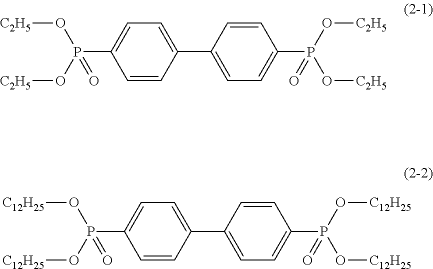

### (Phosphate Compound (C3))

The phosphate compound (C3) is a compound represented by the following formula (3) having a molecular weight of from 400 to 1,500:

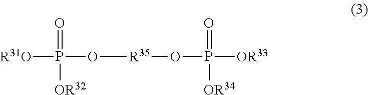

wherein each of R³¹ to R³⁴ which are independent of one another, is an alkyl group or an aryl group which may have an alkyl group, and R³⁵ is a bivalent hydrocarbon group.

In the formula (3), the alkyl group or the aryl group which may have an alkyl group as each of R³¹ to R³⁴ may be the same as the alkyl group or the aryl group which may have an alkyl group as each of R¹¹ to R¹⁴.

R³¹ to R³⁴ may be the same or different from one another.

As each of R³¹ to R³⁴, among the above, preferred is an aryl group which may have an alkyl group, and more preferred is a phenyl group which may have an alkyl group.

The bivalent hydrocarbon group as R³⁵ may be the same as the bivalent hydrocarbon group as R¹⁵.

R³⁵ is preferably an arylene group, more preferably a phenylene group, a biphenylene group or a linked phenylene group having phenylene groups linked via an alkylene group, particularly preferably a phenyl group.

The molecular weight of the phosphate compound (C3) is from 400 to 1,500, more preferably from 600 to 1,500. The molecular weight relates to the decomposition temperature of the phosphate compound. A compound having a molecular weight of at least 400 has a sufficiently high decomposition temperature, hardly generates a decomposition gas in the compounding step and the film formation step, and provides excellent work environment. Further, a compound having a molecular weight within the above range has an excellent effect to suppress the photoactivity of titanium oxide. This is considered to be because the phosphate compound (C3) is uniformly oriented in titanium oxide. Further, foreign matters due to agglomeration of the phosphate compound (C3) itself hardly form.

The phosphorus atom content in the phosphate compound (C3) is preferably at a level of from 4 to 12%.

The melting point of the phosphate compound (C3) is preferably at most the melting point of the fluororesin (A). For example, in a case where the fluororesin (A) is ETFE having a melting point of 240° C., the phosphate compound (C3) is preferably one having a melting point of at most 240° C.

Specific examples of the phosphate compound (C3) includes a compound represented by the following formula (3-1) (resorcinol bis-diphenyl phosphate, molecular weight: 687), a compound represented by the following formula (3-2) (resorcinol bis-dixylenyl phosphate, molecular weight: 879) and bisphenol A bis-diphenyl phosphate.

Such materials are known as phosphorus type flame retardants, and heretofore, their effect to suppress the photoactivity of titanium oxide has not been known.

As the phosphate compound (C3), commercially available products may be used, and products prepared by a known production process may be used. For example, the compound represented by the formula (3-1) may be available as “Aromatic Polyphosphate 733S” manufactured by DAIHACHI CHEMICAL INDUSTRY CO., LTD. Further, the compound represented by the formula (3-2) may be available as “Aromatic Polyphosphate PX200” manufactured by DAIHACHI CHEMICAL INDUSTRY CO., LTD.

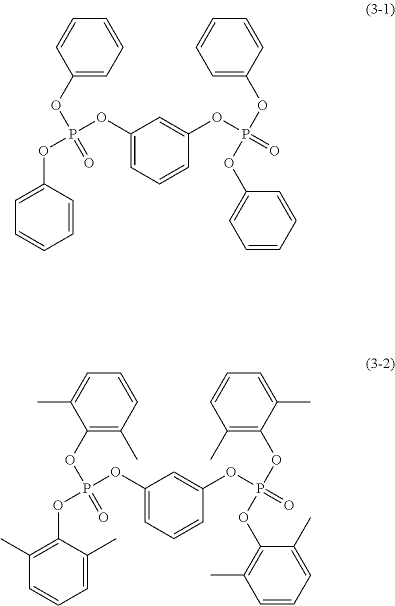

Among the above, in view of a large effect to disperse the particles (B) and a large effect to suppress coloring, preferred is the phosphonite compound (C1) or the phosphonate compound (C2).

In view of a large effect to suppress the photoactivity of titanium oxide, most preferred is the phosphate compound (C3).

As the phosphorus compound (C), one type may be used, or two or more types may be used in combination.

The content of the phosphorus compound (C) in the resin composition is from 0.20 to 2.0 parts by mass, preferably from 0.25 to 1.5 parts by mass per 100 parts by mass of the particles (B). When the content of the phosphorus compound (C) is at least the lower limit of the above range, the phosphorus compound (C) can sufficiently suppress the photoactivity of titanium oxide, and the obtainable resin film will be excellent in the weather resistance and the outer appearance. When the content of the phosphorus compound (C) is at most the upper limit of the above range, bleed out from an obtainable resin film is less likely to occur, and the resin film will be excellent in the outer appearance.

### [Silicone Oil (D)]

The silicone oil (D) is an organopolysiloxane having an organic group.

The primary purpose of incorporating the silicone oil (D) is to reduce attachment of the phosphorus compound (C) to a cylinder or a screw. The silicone oil (D) quickly spreads on the metal surface of e.g. a cylinder or a screw and prevents attachment of the phosphorus compound (C) and the shear heating. Thus, formation of fisheyes at the time of film-forming and coloring are suppressed, and a resin film having a favorable outer appearance will be obtained.

The silicone oil (D) also contributes to improvement of dispersion of the particles (B) and to prevention of coloring. Thus, even when the phosphate compound (C3) having a large effect to suppress the photoactivity of titanium oxide but having a relatively small effect to disperse titanium oxide and effect to suppress coloring is used as the phosphorus compound (C), the particles (B) may sufficiently be dispersed, and coloring may be prevented.

The organic group which the silicone oil (D) has is preferably an alkyl group having at most 4 carbon atoms or a phenyl group.

The silicone oil (D) may, for example, be a straight silicone oil such as dimethyl silicone oil or phenyl methyl silicone oil, an alkyl-modified silicone oil, an alkyl aralkyl-modified silicone oil or a fluorinated alkyl-modified silicone oil. Among them, dimethyl silicone oil is preferred in view of the cost, and phenyl methyl silicone oil is preferred in view of the heat resistance.

The molecular weight of the silicone oil (D) is preferably at most 1,500. When the molecular weight is at most 1,500, for example, an oxygen functional group of aluminum oxide or silicon oxide in the outermost layer of the titanium oxide particles is reacted with the silicone oil (D) with high efficiency thereby to form a uniform and dense surface-treated layer, whereby dispersibility of the particles (B) at the time of film-forming will be more excellent. Further, when the molecular weight is at most 1,500, fluidity of the silicone oil (D) under film-forming temperature conditions tends to be high. The silicone oil (D) is likely to spread on the metal surface of e.g. a cylinder or a screw at the time of film-forming, and has a large effect to suppress the shear heating and a large effect to prevent attachment of the phosphorus compound.

As the silicone oil (D), commercially available products may be used. As the dimethyl silicone oil, SH200 (tradename) manufactured by Dow Corning Toray Co., Ltd., KF96 (tradename) manufactured by Shin-Etsu Chemical Co., Ltd., and TSF451 (tradename) manufactured by Toshiba Silicones, having various molecular weights (viscosities), may, for example, be mentioned. Further, as the phenyl methyl silicone oil, SH510 (tradename), SH550 (tradename) and SH710 (tradename) manufactured by Dow Corning Toray Co., Ltd. and KF54 (tradename) manufactured by Shin-Etsu Chemical Co., Ltd. may, for example, be mentioned.

As the silicone oil (D), one type may be used, or two or more types may be used in combination.

The content of the silicone oil (D) in the resin composition is from 0.2 to 2.5 parts by mass, preferably from 0.5 to 1.8 parts by mass per 100 parts by mass of the particles (B). When the content of the silicone oil (D) is at least the lower limit of the above range, attachment of the phosphorus compound (C) to the cylinder or the screw will sufficiently be suppressed. When the content of the silicone oil (D) is at most the upper limit of the above range, bleed out from an obtainable resin film hardly occurs, and the resin film will be excellent in the outer appearance.

The sum of the content of the phosphorus compound (C) and the content of the silicone oil (D) in the resin composition is preferably at least 1.0 part by mass and at most 3.0 parts by mass per 100 parts by mass of the particles (B). When their total content is at most 3.0 parts by mass, volatile contents from the phosphorus compound (C) and the silicone oil (D) may be suppressed. The film-forming die lip at the time of film-forming will not be contaminated, and continuous forming over a longer period will be possible.

### [Optional Components]

The resin composition as the material of the resin film of the present invention may contain additives other than the particles (B), the phosphorus compound (C) and the silicone oil (D) as the case requires. Such additives may, for example, be an inorganic pigment for coloring, carbon black, an organic pigment or a delustering agent such as silica or alumina.

The thickness of the resin film of the present invention is preferably from 12 to 300 μm, more preferably from 12 to 20 μm. The thinner the film is, the higher the usefulness of the present invention is. Especially, when the thickness is at most 20 μm, it is possible to reduce the cost, whereby it is possible to produce a low-cost resin film.

Of the resin film of the present invention, the surface (for example, in a case where the resin film is used as a film constituting the outermost layer of a backsheet and another layer is laminated to form a backsheet, the surface on which another layer is to be laminated) may be surface-treated. The surface treatment is not particularly limited within a range not to impair the effects of the present invention, and may be properly selected from known surface treatment methods. Specifically, a plasma treatment or a corona discharge treatment may, for example, be mentioned.

The resin film of the present invention can be produced by a known method such as a method of blending the fluororesin (A), the particles (B), the phosphorus compound (C), the silicone oil (D) and other optional components, kneading them to form a resin composition, and forming the resin composition into a film by a known formation method. Further, the surface treatment may be carried out as the case requires.

The order of blending the respective components is not particularly limited, and some of components may sequentially be blended, or the entire components may be blended all at once. As an example of the former, the particles (B) are surface-treated with either one or both of the phosphorus compound (C) and the silicone oil (D), and the surface-treated particles (B) and the other components (the fluororesin (A), the phosphorus compound (C) or the silicone oil (D) not used for the surface treatment, the other optional components, and the like) are kneaded.

As a method of surface-treating the particles (B) with the phosphorus compound (C) or the silicone oil (D), for example, the following methods 1 and 2 may be mentioned. However, the method is not limited thereto, and a known method may be employed.

1. A so-called wet method in which either one or both of the phosphorus compound (C) and the silicone oil (D) are dissolved in a solvent, the particles (B) are added to the resulting solution, and as the case requires, an acid, water or the like is added and mixed, the solvent is removed by drying, and the resulting product is pulverized to obtain surface-treated particles (B).

2. A so-called dry method in which the particles (B) and either one or both of the phosphorus compound (C) and the silicone oil (D) are poured into e.g. a Henschel mixer having a temperature-conditioning function, and they are stirred and dispersed at a temperature of at least a temperature at which these organic agents are liquefied and the mixture has fluidity, to attach the surface-treating agent to the surface.

In these methods, in a case where both surface treatment with the phosphorus compound (C) and surface treatment with the silicone oil (D) are carried out, the respective surface treatments may be carried out simultaneously or separately.

As a method for producing the resin film of the present invention, preferred is a method of adding the particles (B), the phosphorus compound (C) and the silicone oil (D) simultaneously or sequentially to the fluororesin (A), kneading the mixture, and forming the obtained resin composition.

This method is easily conducted as compared with a method of preliminarily surface-treating the particles (B) with the phosphorus compound (C) or the silicone oil (D) and blending the surface-treated particles (B) with the fluororesin (A). Further, the phosphorus compound (C) and the silicone oil (D) are likely to move to the interface between the particles (B) and the resin at the time of kneading particularly in ETFE. Thus, even though the surface treatment with the phosphorus compound (C) or the silicone oil (D) is not preliminarily carried out, the phosphorus compound (C) or the silicone oil (D) is oriented on the surface of the particles (B) at the time of kneading, whereby effects to suppress the photoactivity of the particles (B) and to improve the dispersibility will be obtained.

The resin film of the present invention as explained above has excellent ultraviolet shielding performance and weather resistance since the particles (B) containing titanium oxide as the main component and the phosphorus compound (C) and the silicone oil (D) as well are dispersed in prescribed contents in the fluororesin (A). For example, even in the case of a thin film of at most 20 μm, the ultraviolet shielding properties (for example, an ultraviolet transmittance at a wavelength of at most 360 nm being less than 0.03%) which is required to a backsheet of a solar cell module is exhibited for a long period of time. Further, while titanium oxide is contained in such an amount as to obtain sufficient ultraviolet shielding properties even when the film is so thin as at most 20 μm, change in solar reflectance or deterioration in mechanical strength hardly occurs.

Accordingly, the resin film of the present invention is useful as a backsheet for a solar cell module. For example, by using the resin film of the present invention as a film constituting the outermost layer of a backsheet, it is possible to stably protect a solar cell module for a long period of time.

However, the use of the resin film of the present invention is not limited thereto, and the resin film may be used for e.g. roofs of buildings such as a roof of a warehouse or working facility in agriculture or livestock and a roof of a stadium, a marking film used for e.g. a signboard, or a surface material for wall papers.

Further, the resin film of the present invention is excellent in the outer appearance since at the time of its forming, agglomerates of titanium oxide and the phosphorus compound, fisheyes due to e.g. a decomposed product of the phosphorus compound, bubble streaks due to gas formation hardly occur, even though the resin film of the present invention contains titanium oxide and the phosphorus compound.

Further, the resin film of the present invention can be produced in favorable work environment without emitting an unpleasant odor due to decomposition of the phosphorus compound at the time of its forming. Further, continuous production over 10 hours or more is possible at the time of forming, and the resin film can be produced with excellent continuous productivity.

In the present invention, the phosphorus compound (C) and the silicone oil (D) are considered to have the following effects.

First, the fluororesin (A) represented by ETFE has a high forming temperature exceeding 300° C. The phosphorus compound (C) lacks compatibility with the fluororesin (A) at such a high forming temperature, and is thereby likely to be oriented in the surface layer of the particles (B). This phenomenon is considered to be a phenomenon which occurs in blending with the fluororesin (A) which is to be melt-formed.

Further, the photoactivity of titanium oxide contained in the particles (B) is suppressed by the phosphorus compound (C) being oriented on the surface of the particles (B), although the reason is unclear.

In addition, the phosphorus compound (C) is at the above forming temperature in a liquid state, not in a solid state. It can suppress the shear heating by contact of the particles (B) with a metal member such as a screw, and it can suppress coloring of the resin due to a temperature increase. Particularly, the phosphonite compound (C1) has an effect to reduce the coloring of the resin at the time of compounding at the same level as a phosphite antioxidant as disclosed in JP-A-11-323008 (the above-described Patent Document 8) although it is not an antioxidant.

Further, a phosphite antioxidant has an effect to suppress the photoactivity of titanium oxide. However, it can hardly maintain the performance over a long period. This is considered to be because the phosphite itself is inferior in the light stability (light resistance) and loses its effect, it is inferior in the chemical stability against hydrogen fluoride present in the fluororesin (A) and it loses its effect, or its orientation property in titanium oxide is weak and it leaves the film during long term exposure.

As described above, by using the phosphorus compound (C), the photoactivity of titanium oxide and coloring of the resin at the time of compounding are suppressed. Thus, it is possible to overcome both the problem such that the fluororesin is burnt and a white resin cannot be obtained even though titanium oxide as a white pigment is incorporated, and the problem such that the photoactivity of titanium oxide impairs optical properties and mechanical properties of the fluororesin in the outdoor exposure.

However, a resin film having only the phosphorus compound (C) blended with the fluororesin (A) and the particles (B) have defects. The defects are remarkable particularly in a film having a thickness of about 20 μm.

The phosphorus compound (C) is strongly adsorbed in a metal oxide such as titanium oxide, and accordingly it is adsorbed by orientation in the particles (B) at the time of kneading, and is extruded together with the compounded resin. However, a part of the phosphorus compound (C) is adsorbed in a metal member such as a metal cylinder or a metal screw used for compounding. Such a phosphorus compound (C) stays on the metal member for from about 20 minutes to about 1 hour. Although the phosphorus compound (C) has a relatively high thermal stability, its decomposition or condensation proceeds when it is exposed to a high forming temperature for a long period of time. The phosphorus compound (C) is likely to form a thermally-deteriorated product or agglomerates, and such is considered to be the cause of the above defects.

By further blending the silicone oil (D), defects such that agglomerates are likely to form by burning of the phosphorous compound (C) without impairing the effect of the phosphorus compound (C) to suppress the photoactivity of titanium oxide and to suppress coloring of the resin. Between the phosphorus compound (C) and the silicone oil (D), the phosphorus compound (C) has a lower heat decomposition temperature, and accordingly at the time of forming, the silicone oil (D) functions as a liquid heat resistant material which wets the screw and the cylinder. Thus, the shear heating is suppressed, and attachment of the phosphorus compound (C) to the metal member is reduced, whereby heat decomposition of the phosphorus compound (C) is suppressed, film defects are reduced, and the outer appearance failure is reduced. Further, coloring of the resin is suppressed.

Among the phosphorus compounds (C), the phosphonate compound (C2) has a large effect to suppress the photoactivity of titanium oxide but has a relatively weak effect to suppress coloring of the resin. Even when the phosphonate compound (C2) is used, by use of the silicone oil (D) in combination, an excellent effect to suppress coloring will be obtained.

### <Backsheet>

The backsheet for a solar cell module of the present invention is provided with the above resin film of the present invention.

The resin film of the present invention is suitably used as an outermost film of a multilayer structured backsheet.

The constitution of the multilayer structured backsheet may be the same as the constitution of a known backsheet except that the resin film of the present invention is used as the outermost film.

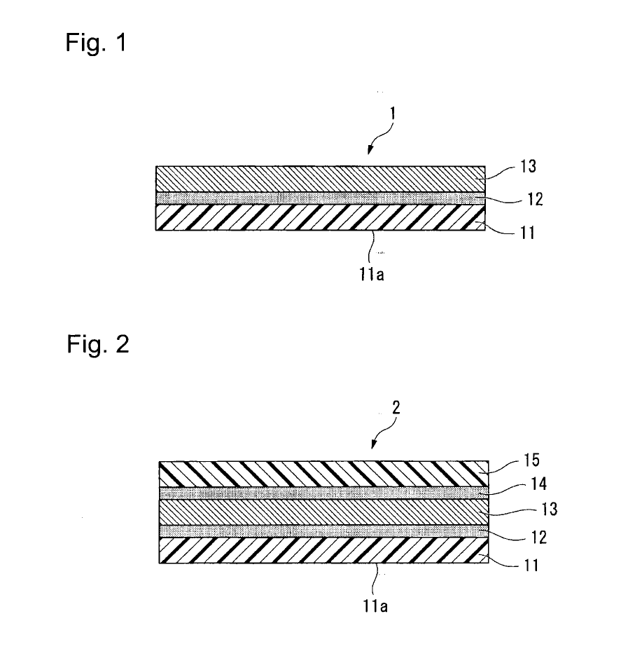

FIG. 1 illustrates one embodiment of the backsheet of the present invention.

A backsheet 1 according to this embodiment is a laminate having an outermost layer 11 in contact with air when used for a solar cell module, an adhesive layer 12 and a moisture-proof layer 13 laminated in this order, and the outermost layer 11 is the resin film of the present invention.

The moisture-proof layer 13 is a layer for protecting a solar cell element from water vapor by suppressing permeation of the water vapor. The moisture-proof layer 13 is not particularly limited, and may properly be selected from known moisture-proof layers used for a backsheet. As a specific example, a polyethylene terephthalate film having a thin film layer made of a metal oxide such as silicon oxide or aluminum oxide provided by vapor deposition or a sputtering method may be exemplified.

The adhesive layer 12 is not particularly limited so long as it is possible to adhere the outermost layer 11 and the moisture-proof layer 13, and it may properly be selected from known adhesives used for adhering a fluororesin film and a moisture-proof layer. For example, one called a two-component curing type urethane-based adhesive may be used.

In the solar cell module, the backsheet 1 is arranged so that the surface 11a on the outermost layer 11 side is in contact with the air.

The backsheet 1 has the resin film of the present invention as an outermost layer and thereby has excellent weather resistance. For example, since the ultraviolet rays entering from the surface 11a at the outermost layer 11 side are shielded, the adhesive layer 12 is hardly deteriorated by the ultraviolet rays, and adhesion between the outermost layer 11 and the moisture-proof layer 13 is hardly deteriorated.

Therefore, according to the backsheet 1, the quality of a solar cell module can be maintained over a long period of time as compared with a conventional backsheet.

Further, in a case where the solar cell module is installed on the slant so as to face the sun, a large quantity of reflected light of sunlight is applied to the backsheet at the rear side of the solar cell module, and therefore it is required to have more excellent weather resistance (such as light resistance or heat resistance), but since the backsheet 1 has an excellent weather resistance, it has a sufficient weather resistance for such a use.

FIG. 2 illustrates another embodiment of the backsheet of the present invention.

A backsheet 2 according to this embodiment is a laminate having a glue layer 14 and a resin layer 15 further laminated on the moisture-proof layer 13 side of the backsheet 1 as shown in FIG. 1.

In the backsheet 2, the resin layer 15 is laminated, whereby the moisture-proof property and the electrical insulation property are further improved as compared with the backsheet 1. The resin film constituting the resin layer 15 is not particularly limited, and the resin film of the present invention may be used, or another resin film may be used. Such another resin film may, for example, be a fluororesin film other than the resin film of the present invention, a nylon film or a polyethylene terephthalate film, and a fluororesin film is preferred. A fluororesin in the fluororesin film may be the same as the above. The fluororesin film used as the resin layer 15 may be one consisting solely of a fluororesin, or may be one containing additives in the fluororesin.

The glue layer 14 is not particularly limited so long as it is possible to adhere the moisture-proof layer 13 and the resin layer 15, and it may properly be selected from known glues.

Further, the backsheet of the present invention is not limited to these embodiments. The respective constitutions, combinations thereof and the like in the above embodiments are mere examples, and it is possible to add, omit and substitute the constitutions and change to others within a range of the present invention.

### <Solar Cell Module>

The solar cell module of the present invention is provided with the backsheet of the present invention.

The constitution of the solar cell module of the present invention may be the same as the constitution of a known solar cell module except that the backsheet of the present invention is used as a backsheet. As a specific example, a solar cell module comprising a transparent substrate, a filler layer having a solar cell element sealed therein and the backsheet in this order, wherein, as the above backsheet, the above-mentioned backsheet 1 or backsheet 2 is arranged so that the outermost layer surface 11a is in contact with the air.

As the transparent substrate, a substrate commonly used for a solar cell module may be used, and for example, a glass substrate may be mentioned. The transparent substrate preferably has a transmittance at a wavelength of from 400 to 1,000 nm of at least 90%. The shape of the transparent substrate is not particularly limited, and may be properly selected depending on the purpose of use.

The solar cell element is an element to convert the sunlight to electric energy, and a solar cell element commonly used for a solar cell module may be used.

The filler layer to seal the solar cell element therein may be formed by a filler commonly used for a solar cell module. The filler may, for example, be EVA (ethylene/vinyl acetate copolymer).

### EXAMPLES

Now, the present invention will be described in detail with reference to Examples. However, the present invention is not limited to the following specific Examples.

Among the after-mentioned Ex. 1 to 49, Ex. 22 to 29, 32 to 37 and 41 to 46 are Examples of the present invention, and Ex. 1 to 21, 30, 31, 38 to 40 and 47 to 48 are Comparative Examples.

Material used in Examples are shown below.

### <Fluororesin (A)>

Fluon ETFE C-88AX (manufactured by Asahi Glass Company, Limited)<

### <Particles (B)>

RCL-69 (manufactured by Millennium Inorganic Chemicals, titanium oxide)
CR470 (manufactured by Tronox, titanium oxide)

With respect to the above RCL-69 and CR470, analysis was carried out in accordance with the following procedure by using a scanning type fluorescent X-ray analyzer ZSX Primus II (manufactured by Rigaku Corporation).

Using a press sheet of the respective particles, in addition to titanium oxide (TiO₂), sodium oxide (Na₂O), aluminum oxide (Al₂O₃), silicon oxide (SiO₂), diphosphorus pentaoxide (P₂O₅), zirconium oxide (ZrO₂) and the like were quantified.

Analysis results are shown in Table 1. The numerical values in Table 1 indicate contents (mass %) or the respective components contained in the respective particles. “Others” are elements not measured. As such elements, carbon was mainly detected. Accordingly, it was found that the respective particles were not a little subjected to surface treatment with e.g. an organic surface treating agent (silicone, trimethylolpropane, ester).

TABLE 1

| | RCL-69 | CR470 |
|---|---|---|
| TiO₂ | 97.6 | 97.1 |
| Na₂O | 0.1 | 0 |
| Al₂O₃ | 1.6 | 2.1 |
| SiO₂ | 0.3 | 0 |
| P₂O₅ | 0 | 0 |
| ZrO₂ | 0 | 0 |
| Others | 0.4 | 0.8 |

### <Silicone Oil (D)>

Reagent A: KF54 (manufactured by Shin-Etsu Chemical Co., Ltd., phenyl methyl silicone oil PMS)<

### <Phosphorus Compound (C) and its Comparative Compound>

Reagent B: ADK STAB PEP36 (manufactured by ADEKA CORPORATION, phosphorus antioxidant, phosphite)
Reagent C: SUMILIZER GP (manufactured by Sumitomo Chemical Company, Limited, phosphorus-phenol antioxidant)
Reagent D: PX200 (manufactured by DAIHACHI CHEMICAL INDUSTRY CO., LTD., aromatic polyphosphate flame retardant, phosphate)
Reagent E: 733S (manufactured by DAIHACHI CHEMICAL INDUSTRY CO., LTD., aromatic polyphosphate flame retardant, phosphate)
Reagent F: SUMILIZER GA-80 (manufactured by Sumitomo Chemical Company, Limited, phenol antioxidant)
Reagent G: SUMILIZER TP-D (manufactured by Sumitomo Chemical Company, Limited, sulfur antioxidant)
Reagent H: GSY-P101 (manufactured by Osaki Industry Co., Ltd., phosphorus processing stabilizer, phosphonite)
Reagent I: IRGAFOS P-EPQ (manufactured by Ciba Specialty Chemicals, phosphorus antioxidant, phosphonite)

Reagent J: Tetradecylbiphenyl-4,4′-diyldiphosphonate (manufactured by JOHOKU CHEMICAL CO., LTD., phosphorus processing stabilizer, phosphonate)

The compound names, the molecular weights and the molecular formulae of the reagents B to J are shown in Table 2.

Among the above, the reagents D, E, H, I and J correspond to the phosphorus compound (C), and the others are comparative compounds.

The reagent D is a compound represented by the formula (3-2), the reagent E is a compound represented by the formula (3-1), the reagent H is a compound represented by the formula (1-1), the reagent I is a compound represented by the formula (1-2), and the reagent J is a compound represented by the formula (2-2).

TABLE 2

| | | Molecular | Molecular |
|---|---|---|---|
| | Compound Name | weight | formula |
| B | Cyclic neopentanetetraylbis(2,6-di-t- | 633 | C₃₅H₅₄O₆P₂ |
| | butyl-4-methylphenoxy)phosphite | | |
| C | 6-[3-(3-t-butyl-4-hydroxy-5- | 661 | C₄₂H₆₁O₄P |
| | methylphenyl)propoxy]-2,4,8,10-tetra-t- | | |
| | butyldibenz[d.f][1,3,2]dioxaphosphepin | | |
| D | Resorcinol bis-dixylenyl phosphate | 879 | C₃₈H₄₀O₈P₂ |
| E | Resorcinol bis-diphenyl phosphate | 687 | C₅₄H₄₀O₈P₂ |
| F | Bis[3-(3-tert-butyl-4-hydroxy-5- | 741 | C₄₃H₆₄O₁₀ |
| | methylphenly)propionyloxy]2,4,8,10- | | |
| | tetraoxaspiro[5.5]undecane-3,9- | | |
| | diyl)bis(2,2-dimethyl-2,1-ethanediyl) | | |
| G | Pentaerythritol tetra(3- | 1,162 | C₆₅H₁₂₄O₈S₄ |
| | dodecylthiopropionate) | | |
| H | Tetrakis(2,4-di-tert-butyl-5- | 1,092 | C₇₂H₁₀₀O₄P₂ |
| | methylphenyl)-4,4′-biphenylene | | |
| | diphosphonite | | |
| I | Tetrakis(2,4-di-tert-butylphenyl){1,1- | 1,035 | C₆₈H₉₂O₄P₂ |
| | biphenyl}-4,4′-diyl bisphosphonate | | |
| J | Tetradodecylbiphenyl-4,4′-diyl | | |
| | diphosphonate | 986 | C₆₀H₁₀₈O₆P₂ |

### Ex. 1 to 10

Parts by mass of Fluon ETFE C88AX, 8.98 parts by mass of RCL-69 and 0.134 part by mass of the reagent (any one of A to J) were blended. 0.134 Part by mass of the reagent corresponds to 1.5 parts by mass per 100 parts by mass of titanium oxide. Then, the mixture was extruded from a 35 mm co-rotating twin screw extruder (TEM35, manufactured by Toshiba Machine Co., Ltd.) at a temperature of 320° C. in a discharge amount of 20 kg per hour to obtain 10 types of titanium oxide-containing pellets.

The 10 types of titanium oxide-containing pellets were respectively dried at 150° C. for 1 hour, and then extruded under the following extrusion conditions to form fluororesin films having a thickness of 20 μm and fluororesin films having a thickness of 100 μm.

### (Extrusion Conditions)

A 30 mm single screw extruder having a 450 mm T-die attached to the tip was used as a forming machine. The film discharged from the T-die was passed between a mirror surface roll kept at 150° C. and a silicone embossing roll kept at 100° C. while being nipped to apply corona discharge treatment on both surfaces, to obtain a desired fluororesin film. Corona discharge treatment was carried out for increasing an adhesive force when the fluororesin film is laminated with e.g. a PET film by using an adhesive in production of a backsheet.

### Ex. 11 to 20

Fluororesin films (thickness: 20 μm, thickness: 100 μm) were prepared in the same manner as in Ex. 1 to 10 except that CR470 was used in the same blend amount instead of RCL-69, and 0.0895 part by mass of the reagent (any one of A to J) was blended. 0.0895 Part by mass of the reagent corresponds to 1.0 part by mass per 100 parts by mass of titanium oxide.

### [Evaluation]

In each of Ex. 1 to 20, gas formation when the fluororesin film having a thickness of 100 μm was prepared was visually confirmed, and the odor was also evaluated.

Further, the obtained fluororesin film was evaluated as follows.

The results are shown in Tables 3 to 4.

### (Reflection b*)

With respect to the fluororesin film having a thickness of 100 μm immediately after preparation, its degree of coloring was measured by a color meter (SM Colour Meter SM-T manufactured by Suga Test Instruments Co., Ltd.) by measuring b* of the reflected light. The b* value is a negative value when the reflected color is bluish, and it is a positive value when the reflected color is yellowish. The resin was judged to be burnt and become yellowish when the b* value exceeded 0.8.

### (Fisheyes)

An outer appearance test was conducted on 3 m of the fluororesin film having a thickness of 20 μm immediately after preparation. The number of film defects such as agglomerates of titanium oxide, agglomerates of each of the reagents A to J and thermally-deteriorated products were counted as “fisheyes”.

### (360 nm Transmittance)

With respect to the fluororesin film having a thickness of 20 μm immediately after preparation, the transmittance (%) at 360 nm was measured by UV-PC3300 measuring apparatus manufactured by Shimadzu Corporation.

### (Change of Solar Reflectance)

With respect to the fluororesin film having a thickness of 20 μm immediately after preparation, the solar reflectance (%) as stipulated by JIS R3106 was measured by UV-PC3300 measuring apparatus manufactured by Shimadzu Corporation.

Separately, the fluororesin film having a thickness of 20 μm immediately after preparation was cut into a size of 6 cm×4 cm to prepare an evaluation sample. This evaluation sample was put in an accelerated weather resistance test apparatus (manufactured by Suga Test Instruments Co., Ltd., Sunshine 300) and exposed for 10,000 hours. As the exposure condition, the black panel temperature was 63° C.

With respect to the evaluation sample after the exposure for 10,000 hours, the solar reflectance (solar reflectance after the test) was measured in the same manner as the above to calculate a difference in the solar reflectance between before and after the exposure test (solar reflectance after the test−solar reflectance before the test), which is regarded as “the solar reflectance difference”.

A small change in the solar reflectance after the accelerated weather resistance test means that the photoactivity of titanium oxide is highly suppressed. For example, in a case where the photoactivity is not suppressed, titanium oxide moves toward a site where light or water is applied in the film during the test, whereby the film is further whitened (whitening), and therefore the solar reflectance is increased to increase the solar reflectance difference. The degree of the solar reflectance difference is meant by the degree of the absolute value.

Further, in measurement of the solar reflectance, the parallelism between a film and a light source affects a measurement value of the reflectance, and in the case of a thin and soft film having a thickness of about 20 μm, a slight curl tends to occur thereby to cause an error of approximately ±0.5%. Further, the accelerated weather resistance test is a carbon arc type test, and therefore samples tend to be contaminated by combustion of carbon during the exposure test even though water is sprayed on the samples. Accordingly, there is a case where the solar reflectance decreases by approximately 1.0%. Accordingly, even in a case where the photoactivity is not developed at all, a change in the solar reflectance of an increase up to 0.5% or a reduction to 1.5% after the accelerated weather resistance test may be considered. Accordingly, when the solar reflectance difference is within a range of from −1.5 to 0.5%, such a film may be judged as a film having a favorable weather resistance of which the photoactivity is sufficiently suppressed during the accelerated weather resistance test.

TABLE 3

| | | Particles (B): RCL-69 | | | | |
|---|---|---|---|---|---|---|
| | | | | 20 μm film | | |
| | | 100 μm film | | | 360 nm | Solar |
| | | | Gas formation | | transmittance | reflectance |
| | Reagent | Reflection b* | (odor) | Fisheyes | (%) | difference (%) |
| Ex. 1 | A | 0.30 | Nil | 0 | <0.01 | 3.6 |
| Ex. 2 | B | 0.17 | Formed | 3 | <0.01 | 2.3 |
| Ex. 3 | C | 0.70 | Formed | 2 | <0.01 | 3.6 |
| Ex. 4 | D | 1.26 | Nil | 6 | <0.01 | 0 |
| Ex. 5 | E | 1.65 | Nil | 5 | <0.01 | −0.1 |
| Ex. 6 | F | 1.80 | Nil | 10 | <0.01 | 3.1 |
| Ex. 7 | G | 0.44 | Nil | 2 | <0.01 | 3.4 |
| Ex. 8 | H | 0.05 | Nil | 2 | <0.01 | −0.1 |
| Ex. 9 | I | 0.29 | Nil | 3 | <0.01 | −0.1 |
| Ex.10 | J | 0.28 | Nil | 3 | <0.01 | −0.1 |

TABLE 4

| | | Particles (B): CR470 | | | | |
|---|---|---|---|---|---|---|
| | | | | 20 μm film | | |
| | | 100 μm film | | | 360 nm | Solar |
| | | | Gas formation | | transmittance | reflectance |
| | Reagent | Reflection b* | (odor) | Fisheyes | (%) | difference (%) |
| Ex.11 | A | −0.30 | Nil | 0 | <0.01 | 3.2 |
| Ex.12 | B | 0.14 | Formed | 4 | <0.01 | 1.3 |
| Ex.13 | C | 0.46 | Formed | 5 | <0.01 | 0.1 |
| Ex.14 | D | 0.86 | Nil | 6 | <0.01 | −0.2 |
| Ex.15 | E | 0.83 | Nil | 10 | <0.01 | −0.3 |
| Ex.16 | F | 1.77 | Nil | 3 | <0.01 | 3.6 |
| Ex.17 | G | 0.37 | Nil | 4 | <0.01 | 2.9 |
| Ex.18 | H | 0.21 | Nil | 4 | <0.01 | −0.1 |
| Ex.19 | I | 0.31 | Nil | 3 | <0.01 | −0.2 |
| Ex.20 | J | 0.28 | Nil | 7 | <0.01 | −0.2 |

The fluororesin films obtained in Examples had a 360 nm transmittance of less than 0.01% even though they had a thickness of 20 μm, and had ultraviolet shielding properties (an ultraviolet transmittance at a wavelength of at most 360 nm being less than 0.03%) required for a film constituting the outermost layer of a backsheet. However, they had the following problems.

In Ex. 1 and 11 in which the reagent A was used, the film had a large solar reflectance difference between before and after the accelerated weather resistance test and had a problem in the weather resistance.

In Ex. 2 and 12 in which the reagent B was used, a gas formed, and the film had problems in the weather resistance and the outer appearance (fisheyes).

In Ex. 3 and 13 in which the reagent C was used, a gas formed, and the film had a problem in the outer appearance (fisheyes). Particularly in Ex. 3 in which RCL-69 was used, the film had a problem also in the weather resistance.

In Ex. 4 and 14 in which the reagent D was used, and in Ex. 5 and 15 in which the reagent E was used, the film had a problem in the outer appearance (fisheyes and coloring).

In Ex. 6 and 16 in which the reagent F was used, the film had problems in the weather resistance and the outer appearance (fisheyes and coloring).

In Ex. 7 and 17 in which the reagent G was used, the film had problems in the weather resistance and the outer appearance (fisheyes).

In Ex. 8 and 18 in which the reagent H was used, in Ex. 9 and 19 in which the reagent I was used and in Ex. 10 and 20 in which the reagent J was used, the film had a problem in the outer appearance (fisheyes).

### Ex. 21 to 30

100 Parts by mass of Fluon ETFE C88AX, 8.98 parts by mass of RCL-69, the reagent A in a blend amount as shown in Table 5 and the reagent D in a blend amount as shown in Table 5 were blended, and the mixture was extruded from a 35 mm co-rotating twin screw extruder (TEM35, manufactured by Toshiba Machine Co., Ltd.) at a temperature of 320° C. in a discharge amount of 20 kg per hour to obtain 10 types of titanium oxide-containing pellets.

The blend amounts (parts by mass) of the reagents in Table 5 represent the blend amounts (parts by mass) of the reagents A and D per 100 parts by mass of titanium oxide.

The obtained titanium oxide-containing pellets were respectively dried at 150° C. for 1 hour and extruded under the same extrusion conditions as in Ex. 1 to form fluororesin films having a thickness of 20 μm and fluororesin films having a thickness of 100 μm.

With respect to the obtained fluororesin films, the reflection b*, the fisheyes, the 360 nm transmittance and the solar reflectance difference were evaluated in the same manner as above. The results are shown in Table 5.

TABLE 5

| | Reagent blend | | Particles (B): RCL-69 | | | |
|---|---|---|---|---|---|---|
| | amount [per 100 | | | 20 μm film | | |
| | parts by mass of | | 100 μm | | | Solar |
| | particles (B)] | | film | | 360 nm | reflectance |
| | A (parts | D (parts | Reflection | | transmittance | difference |
| | by mass) | by mass) | b* | Fisheyes | (%) | (%) |
| Ex.21 | 0.10 | 1.40 | 1.00 | 5 | <0.01 | −0.5 |
| Ex.22 | 0.20 | 1.40 | 0.65 | 0 | <0.01 | −0.8 |
| Ex.23 | 0.30 | 1.20 | 0.55 | 0 | <0.01 | −0.7 |
| Ex.24 | 0.50 | 1.00 | 0.65 | 0 | <0.01 | −0.5 |
| Ex.25 | 0.75 | 0.75 | 0.65 | 0 | <0.01 | 0.2 |
| Ex.26 | 1.00 | 0.50 | 0.45 | 0 | <0.01 | 0.2 |
| Ex.27 | 1.25 | 0.25 | 0.30 | 0 | <0.01 | −0.2 |
| Ex.28 | 1.00 | 0.25 | 0.34 | 0 | <0.01 | 0.1 |
| Ex.29 | 2.00 | 0.25 | 0.25 | 0 | <0.01 | 0.3 |
| Ex.30 | 1.35 | 0.15 | 0.22 | 0 | <0.01 | 1.2 |

As shown from the above results, in Ex. 22 to 29 in which the reagent D was blended within a range of from 0.20 to 2.0 parts by mass per 100 parts by mass of the particles (B) and the reagent A was blended within a range of from 0.2 to 2.5 parts by mass per 100 parts by mass of the particles (B), the b* value was low, and the coloring was suppressed. Further, the film had no fisheyes. Further, the solar reflectance difference was within a range of from −1.5 to 0.5%, and the film was excellent in the weather resistance. Thus, it was confirmed that the photoactivity of titanium oxide was sufficiently suppressed.

Whereas in Ex. 21 in which the blend amount of the reagent A was 0.10 part by mass per 100 parts by mass of the particles (B), although the film was excellent in the weather resistance, the film was colored and had many fisheyes.

In Ex. 30 in which the blend amount of the reagent D was 0.15 part by mass per 100 parts by mass of the particles (B), the solar reflectance difference was large, and the film was inferior in the weather resistance.

### Ex. 31 to 39

Fluororesin films having a thickness of 20 μm and fluororesin films having a thickness of 100 μm were prepared in the same manner as in Ex. 21 to 30 in which the reagent H was used instead of the reagent D and the reagents A and H were blended in blend amounts as shown in Table 6.

With respect to the obtained fluororesin films, the reflection b*, the fisheyes, the 360 nm transmittance and the solar reflectance difference were evaluated. The results are shown in Table 6.

TABLE 6

| | Reagent blend | | Particles (B): RCL-69 | | | |
|---|---|---|---|---|---|---|
| | amount [per 100 | | | 20 μm film | | |
| | parts by mass of | | 100 μm | | | Solar |
| | particles (B)] | | film | | 360 nm | reflectance |
| | A (parts | H (parts | Reflection | | transmittance | difference |
| | by mass) | by mass) | b* | Fisheyes | (%) | (%) |
| Ex.31 | 0.10 | 1.40 | 0.10 | 3 | <0.01 | −0.3 |
| Ex.32 | 0.20 | 1.40 | 0.15 | 0 | <0.01 | −0.2 |
| Ex.33 | 0.30 | 1.20 | 0.20 | 0 | <0.01 | −0.3 |
| Ex.34 | 0.50 | 1.00 | 0.22 | 0 | <0.01 | −0.2 |
| Ex.35 | 0.75 | 0.75 | 0.23 | 0 | <0.01 | −0.3 |
| Ex.36 | 1.00 | 0.50 | 0.18 | 0 | <0.01 | −0.2 |
| Ex.37 | 1.00 | 0.25 | 0.17 | 0 | <0.01 | 0.2 |
| Ex.38 | 1.35 | 0.15 | 0.19 | 0 | <0.01 | 0.9 |
| Ex.39 | 2.00 | 0.15 | 0.21 | 0 | <0.01 | 0.7 |

As shown from the above results, in Ex, 32 to 37 in which the reagent H was blended within a range of from 0.20 to 2.0 parts by mass per 100 parts by mass of the particles (B) and the reagent A was blended within a range of from 0.2 to 2.5 parts by mass per 100 parts by mass of the particles (B), the b* value was low, and the coloring was suppressed. Further, the film had no fisheyes. Further, the solar reflectance difference was within a range of from −1.5 to 0.5%, and the film was excellent in the weather resistance. Thus, it was confirmed that the photoactivity of titanium oxide was sufficiently suppressed.

Whereas in Ex. 31 in which the blend amount of the reagent A was 0.10 part by mass per 100 parts by mass of the particles (B), the film was excellent in the weather resistance and its coloring was suppressed, however, the film had many fisheyes.

In Ex. 38 and 39 in which the blend amount of the reagent H was 0.15 part by mass per 100 parts by mass of the particles (B), the solar reflectance difference was large, and the film was inferior in the weather resistance.

### Ex. 40 to 48

Fluororesin films having a thickness of 20 μm and fluororesin films having a thickness of 100 μm were prepared in the same manner as in Ex. 31 to 39 except that CR470 was used in the same blend amount instead of RCL-69 and the reagent J was used instead of the reagent D.

With respect to the obtained fluororesin films, the reflection b*, the fisheyes, the 360 nm transmittance and the solar reflectance difference were evaluated in the same manner as above. The results are shown in Table 7.

TABLE 7

| | Reagent blend | | Particles (B): CR470 | | | |
|---|---|---|---|---|---|---|
| | amount [per 100 | | | 20 μm film | | |
| | parts by mass of | | 100 μm | | | Solar |
| | particles (B)] | | film | | 360 nm | reflectance |
| | A (parts | J (parts | Reflection | | transmittance | difference |
| | by mass) | by mass) | b* | Fisheyes | ( %) | (%) |
| Ex.40 | 0.10 | 1.40 | 0.10 | 3 | <0.01 | −0.3 |
| Ex.41 | 0.20 | 1.40 | 0.09 | 0 | <0.01 | −0.2 |
| Ex.42 | 0.30 | 1.20 | 0.10 | 0 | <0.01 | −0.3 |
| Ex.43 | 0.50 | 1.00 | 0.29 | 0 | <0.01 | −0.2 |
| Ex.44 | 0.75 | 0.75 | 0.23 | 0 | <0.01 | −0.3 |
| Ex.45 | 1.00 | 0.50 | 0.23 | 0 | <0.01 | −0.2 |
| Ex.46 | 1.00 | 0.25 | 0.09 | 0 | <0.01 | 0.2 |
| Ex.47 | 1.35 | 0.15 | 0.29 | 0 | <0.01 | 0.7 |
| Ex.48 | 2.00 | 0.15 | 0.23 | 0 | <0.01 | 0.9 |

As shown from the above results, in Ex. 41 to 46 in which the reagent J was blended within a range of from 0.20 to 2.0 parts by mass per 100 parts by mass of the particles (B) and the reagent A was blended within a range of from 0.2 to 2.5 parts by mass per 100 parts by mass of the particles (B), the b* value was low, and the coloring was suppressed. Further, the film had no fisheyes. Further, the solar reflectance difference was within a range of from −1.5 to 0.5%, and the film was excellent in the weather resistance. Thus, it was confirmed that the photoactivity of titanium oxide was sufficiently suppressed.

Whereas in Ex. 40 in which the blend amount of the reagent A was 0.10 part by mass per 100 parts by mass of the particles (B), the film was excellent in the weather resistance, and the coloring was suppressed, however, the film had many fisheyes.

In Ex. 47 and 48 in which the blend amount of the reagent J was 0.15 part by mass per 100 parts by mass of the particles (B), the solar reflectance difference was large, and the film was inferior in the weather resistance.

### INDUSTRIAL APPLICABILITY

The resin film of the present invention has excellent ultraviolet shielding properties and weather resistance. For example, even when the resin film is a thin film of at most 20 μm, ultraviolet shielding properties (for example, an ultraviolet transmittance at a wavelength of at most 360 nm being less than 0.03%) which is required for a backsheet of a solar cell module are exhibited over a long period. Further, although the resin film contains titanium oxide in an amount sufficient to obtain a sufficient ultraviolet shielding effect even when it is a thin film of at most 20 μm, its solar reflectance difference is small, and its mechanical strength is hardly decreased.

Accordingly, the resin film of the present invention is useful for a backsheet for a solar cell module. For example, by using the resin film of the present invention as a film constituting the outermost layer of a backsheet, a solar cell module can be protected stably over a long period.

The application of the resin film of the present invention is not limited thereto, and it may be used for e.g. roofs of buildings such as a roof of a warehouse or working facility in agriculture or livestock and a roof of a stadium, a marking film used for e.g. a signboard, or a surface material for wall papers.

This application is a continuation of PCT Application No. PCT/JP2013/079315 filed on Oct. 29, 2013, which is based upon and claims the benefit of priority from Japanese Patent Application No. 2012-239084 filed on Oct. 30, 2012. The contents of those applications are incorporated herein by reference in their entireties.

### REFERENCE SYMBOLS

1: Backsheet
2: Backsheet
11: Outermost layer
12: Adhesive layer
13: Moisture-proof layer
14: Glue layer
15: Resin layer

What is claimed is:

1. A resin film comprising a resin composition containing a fluororesin (A), particles (B) containing titanium oxide as the main component, a phosphorus compound (C) and a silicone oil (D), wherein
the phosphorus compound (C) is at least one member selected from the group consisting of a phosphonite compound (C1) represented by the following formula (1) having a molecular weight of from 600 to 1,500, a phosphonate compound (C2) represented by the following formula (2) having a molecular weight of from 400 to 1,500, and a phosphate compound (C3) represented by the following formula (3) having a molecular weight of from 400 to 1,500,
the content of the phosphorus compound (C) is from 0.20 to 2.0 parts by mass per 100 parts by mass of the particles (B), and
the content of the silicone oil (D) is from 0.2 to 2.5 parts by mass per 100 parts by mass of the particles (B): 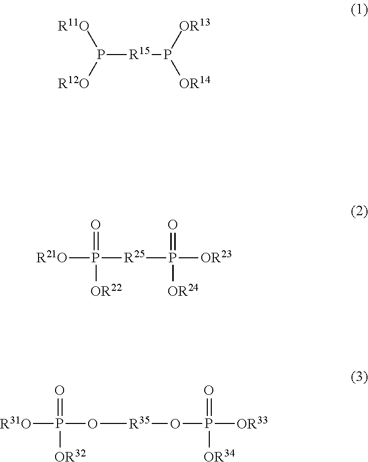
[in the formula (1), each of R¹¹ to R¹⁴ which are independent of one another, is an alkyl group or an aryl group which may have an alkyl group, and R¹⁵ is a bivalent hydrocarbon group; in the formula (2), each of R²¹ to R²⁴ which are independent of one another, is an alkyl group or an aryl group which may have an alkyl group, and R²⁵ is a bivalent hydrocarbon group; and in the formula (3), each of R³¹ to R³⁴ which are independent of one another, is an alkyl group or an aryl group which may have an alkyl group, and R³⁵ is a bivalent hydrocarbon group.]

2. The resin film according to claim 1, wherein each of R¹⁵, R²⁵ and R³⁵ is an alkylene group or an arylene group.

3. The resin film according to claim 1, wherein the phosphorus compound (C) has a phosphorus atom content of from 4 to 12 mass %.

4. The resin film according to claim 1, wherein the phosphonite compound (C1) has a molecular weight of from 1,000 to 1,500, the phosphonate compound (C2) has a molecular weight of from 900 to 1,500, and the phosphate compound (C3) has a molecular weight of from 600 to 1,500.

5. The resin film according to claim 1, wherein the fluororesin (A) is an ethylene/tetrafluoroethylene copolymer.

6. The resin film according to claim 5, wherein the phosphorus compound (C) has a melting point of at most 240° C.

7. The resin film according to claim 1, wherein the particles (B) are particles having a titanium oxide content of at least 95 mass % and an average particle size of from 0.15 to 0.40 μm.

8. The resin film according to claim 1, wherein the content of the particles (B) is from 2 to 15 parts by mass per 100 parts by mass of a resin component in the resin composition.

9. The resin film according to claim 1, wherein the silicone oil (D) is dimethyl silicone oil or phenyl methyl silicone oil.

10. The resin film according to claim 1, which has a thickness of from 12 to 300 μm.

11. The resin film according to claim 1, which is a film obtained by extruding the resin composition into a film.

12. The resin film according to claim 1, which is used for a backsheet for a solar cell module.

13. A backsheet for a solar cell module, which has the resin film as defined in claim 1.

14. The backsheet for a solar cell module according to claim 13, which has the resin film as the outermost layer.

15. A solar cell module provided with the backsheet as defined in claim 13.
